(19) United States
(12) Patent Application Publication
(10) Pub. No.: US 2014/0233195 A1
(43) Pub. Date: Aug. 21, 2014

(54) SEMICONDUCTOR DEVICE

(71) Applicant: Kabushiki Kaisha Toshiba, Minato-ku (JP)

(72) Inventors: Takeshi IKUTA, Yokohama-shi (JP); Kazuhide DOI, Yokohama-shi (JP)

(73) Assignee: Kabushiki Kaisha Toshiba, Minato-ku (JP)

(21) Appl. No.: 14/013,323

(22) Filed: Aug. 29, 2013

Related U.S. Application Data
(60) Provisional application No. 61/767,446, filed on Feb. 21, 2013.

(51) Int. Cl. H05K 5/00

(52) U.S. Cl. CPC H05K 5/0026
USPC 361/752

(57) ABSTRACT

According to one embodiment, a semiconductor device includes a housing, a board in the housing, a semiconductor component on the board, a controller on the board, a first terminal, and a second terminal. The first terminal is exposed to an outside of the housing and electrically connected to the semiconductor component via the controller. The second terminal is on the board in the housing and is electrically connected to the semiconductor component.

### CROSS-REFERENCE TO RELATED APPLICATIONS

This application claims the benefit of U.S. Provisional Application No. 61/767,446, filed Feb. 21, 2013, the entire contents of which are incorporated herein by reference.

### FIELD

Embodiments described herein relate generally to semiconductor devices.

### BACKGROUND

A USB (Universal Serial Bus) memory including a semiconductor memory chip has been proposed.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating a semiconductor device and an external apparatus according to a first embodiment;

FIG. 2 is an exemplary perspective view illustrating the semiconductor device illustrated in FIG. 1;

FIG. 3 is an exemplary cross-sectional view illustrating the semiconductor device illustrated in FIG. 2;

FIG. 4 is an exemplary plan view illustrating the inside of the semiconductor device illustrated in FIG. 2;

FIG. 5 is an exemplary diagram schematically illustrating a portion of electrical connection in the semiconductor device illustrated in FIG. 2;

FIG. 6 is an exemplary plan view illustrating the inside of a semiconductor device according to a second embodiment;

FIG. 7 is an exemplary plan view illustrating the inside of a semiconductor device according to a third embodiment;

FIG. 8 is an exemplary plan view illustrating the inside of a semiconductor device according to a fourth embodiment;

FIG. 9 is an exemplary plan view illustrating the inside of a semiconductor device according to a fifth embodiment;

FIG. 10 is an exemplary cross-sectional view illustrating a first modification of the semiconductor device according to the first to fourth embodiments;

FIG. 11 is an exemplary cross-sectional view illustrating a second modification of the semiconductor device according to the first to fourth embodiments; and

FIG. 12 is an exemplary cross-sectional view illustrating a third modification of the semiconductor device according to the first to fourth embodiments.

### DETAILED DESCRIPTION

Various embodiments will be described hereinafter with reference to the accompanying drawings.

In general, according to one embodiment, a semiconductor device comprises a housing, a board in the housing, a semiconductor component on the board, a controller on the board, a first terminal, and a second terminal. The first terminal is exposed to an outside of the housing and electrically connected to the semiconductor component via the controller. The second terminal is on the board in the housing and is electrically connected to the semiconductor component.

In this specification, some components are expressed by two or more terms. Those terms are just examples. Those components may be further expressed by another or other terms. And the other components which are not expressed by two or more terms may be expressed by another or other terms.

The drawings are schematically illustrated. In the drawings, in some cases, the relationship between a thickness and planar dimensions or the scale of the thickness of each layer may be different from the actual relationship or scale. In addition, in the drawings, components may have different dimensions or scales.

### First Embodiment

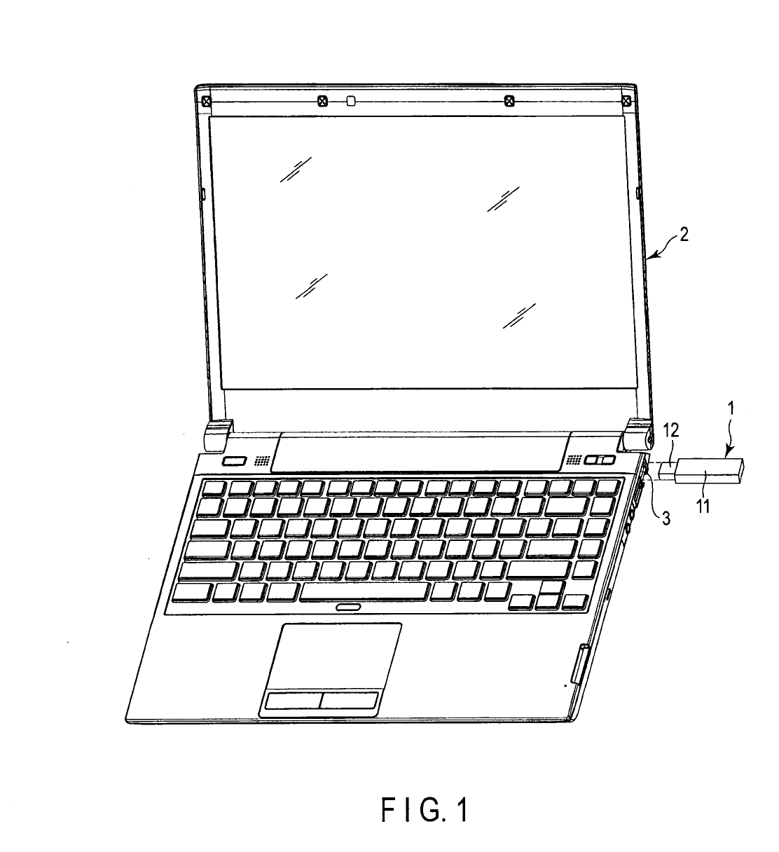

FIGS. 1 to 5 illustrate a semiconductor device 1 according to a first embodiment. The semiconductor device 1 is, for example, a semiconductor memory and an example of the semiconductor memory is a USB memory.

FIG. 1 is a perspective view illustrating the semiconductor device 1 and an external apparatus 2 (e.g., a host apparatus) to which the semiconductor device 1 is connected. The external apparatus 2 is, for example, various kinds of electronic apparatuses (e.g., an information processing apparatus) and may be a personal computer, a tablet terminal, or a server to be connected to a network.

As illustrated in FIG. 1, the external apparatus 2 includes a connector 3 (i.e., an external connector) to which the semiconductor device 1 is to be connected. The connector 3 is, for example, a female connector (i.e., a host) based on a USB standard.

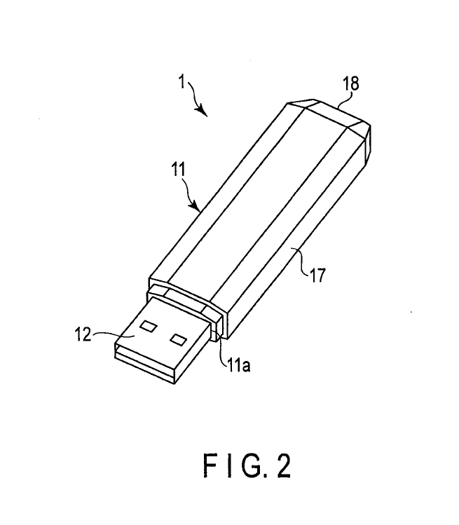

FIGS. 2 to 4 are diagrams illustrating in detail the semiconductor device 1 according to this embodiment. In FIG. 4, for convenience of explanation, a housing 11 is not illustrated. The semiconductor device 1 includes the housing 11, a connector 12, a board 13, a memory card 14, a controller chip 15, and an electronic component 16.

The housing 11 (i.e., a shell, a case, a casing, an outer frame, a container, or a protective portion) is a container having, for example, a substantially rectangular shape in a cross-sectional view. For example, the housing 11 is made of metal, but the material forming the housing 11 is not limited thereto. For example, the housing 11 may be made of hard plastic or other materials. The housing 11 includes a cylindrical circumferential wall 17 (i.e., a first wall) and a rear wall 18 (i.e., a second wall). The rear wall 18 extends in a direction intersecting (e.g., substantially perpendicular to) the circumferential wall 17 and covers the rear end of the circumferential wall 17.

The connector 12 is provided at the leading end of the housing 11. The housing 11 includes, for example, an opening 11a corresponding to the outward shape of the connector 12. The connector 12 protrudes from the opening 11a to the outside of the housing 11. That is, the connector 12 extends outward from the inside of the housing 11 and is exposed to the outside of the housing 11.

The connector 12 is, for example, a male connector based on the USB standard. The connector 12 is to be connected (e.g., inserted into) to the connector 3 of the external apparatus 2 and is to be electrically connected to the external apparatus 2. The connector 12 includes a plurality of (e.g., four) terminals 21 (i.e., connection terminals, connection portions, or conductive portions). The terminals 21 of the connector 12 are exposed to the outside of the housing 11.

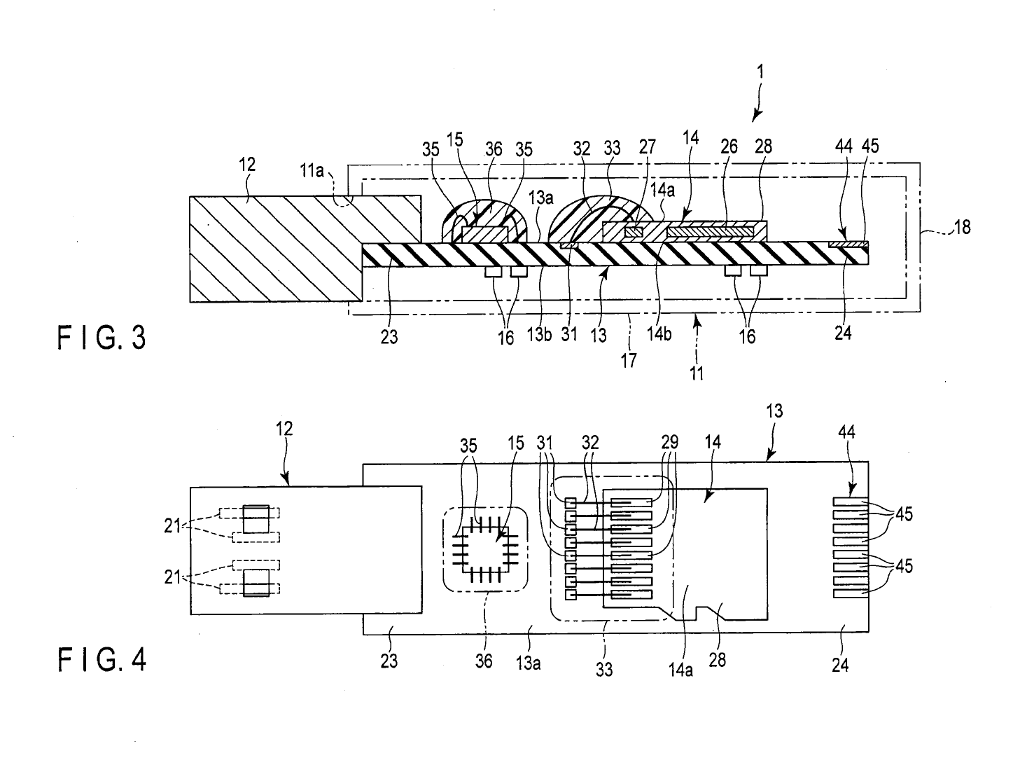

As illustrated in FIGS. 3 and 4, the board 13 (e.g., a circuit board) has a wiring pattern, is accommodated in the housing 11, and is not seen from the outside. The board 13 is, for example, a plate with a substantially rectangular shape and extends substantially in parallel to the circumferential wall 17 of the housing 11. The board 13 includes a first end 23 and a second end 24. The connector 12 is attached to the first end 23. The second end 24 is opposite to the first end 23 and faces the rear wall 18 of the housing 11.

The board 13 includes a first surface 13a and a second surface 13b opposite to the first surface 13a. The first surface 13a and the second surface 13b extend substantially in parallel to the circumferential wall 17 of the housing 11. The first surface 13a and the second surface 13b face the inner surface of the circumferential wall 17 of the housing 11.

The memory card 14 is an example of a “semiconductor component” or a “semiconductor memory component”. In this embodiment, the memory card 14 is, for example, a “micro SD card”. In addition, the memory card 14 may be a “mini SD card”, an “SD card”, or other types of memory cards.

The memory card 14 includes a semiconductor chip 26, a controller chip 27 (i.e., a controller, e.g., a memory card controller), and a sealing member 28. The semiconductor chip 26 is, for example, an arbitrary memory chip (e.g., a semiconductor memory chip) and is, for example, a NAND flash memory chip.

The controller chip 27 is electrically connected to the semiconductor chip 26 in the memory card 14. The controller chip 27 controls, for example, the overall operation of the memory card 14. The controller chip 27 performs control (e.g., access control) for the semiconductor chip 26. That is, the controller chip 27 controls a data writing operation, a data storage operation, a data reading operation, and a data deletion operation for the semiconductor chip 26.

The sealing member 28 (e.g., a resin portion, a mold, or a mold resin) covers the semiconductor chip 26 and the controller chip 27 and forms the outward shape of the memory card 14. An example of the sealing member 28 is a resin (e.g., an epoxy resin).

The memory card 14 includes a first surface 14a and a second surface 14b opposite to the first surface 14a. A plurality of (e.g., eight) terminals 29 (i.e., card terminals, connection terminals, connection portions, or conductive portions) are provided on the first surface 14a. The terminals 29 are exposed to the outside of the memory card 14 and are electrically connected to the controller chip 27. That is, the terminals 29 are electrically connected to the semiconductor chip 26 via the controller chip 27. The terminals 29 are laid in the standard array (i.e., arrangement) of, for example, the “micro SD card” or other memory cards.

As illustrated in FIGS. 3 and 4, the memory card 14 is attached the first surface 13a of the board 13, with the terminals 29 facing the side of the memory card 14 opposite to the board 13. That is, the second surface 14b of the memory card 14 is attached to the first surface 13a of the board 13. The second surface 14b of the memory card 14 is fixed to the first surface 13a of the board 13 by, for example, an adhesive.

A plurality of pads 31 (i.e., connection portions or conductive portions) are provided in the vicinity of, for example, the memory card 14 on the first surface 13a of the board 13. The number of pads 31 is equal to, for example, the number of terminals 29 of the memory card 14 and is, for example, eight.

Bonding wires 32 are provided between the terminals 29 of the memory card 14 and the pads 31 of the board 13. The bonding wires 32 connect the terminals 29 of the memory cards 14 and the pads 31 of the board 13 in a one-to-one manner. In this way, the memory card 14 is electrically connected to the board 13 through the bonding wires 32.

A first sealing portion 33 (e.g., resin, resin portion, sealing resin) is provided on the first surface 13a of the board 13. The first sealing portion 33 covers the bonding wires 32 and the terminals 29 of the memory card 14 and protects the bonding wires 32 and the terminals 29 of the memory card 14.

As illustrated in FIGS. 3 and 4, the controller chip 15 (i.e., a controller, e.g., a USB memory controller) is attached to the first surface 13a of the board 13. An example of the controller chip 15 is a bare chip. The controller chip 15 is connected to the pads of the board 13 through bonding wires 35. In this way, the controller chip 15 is electrically connected to the board 13 through the bonding wires 35.

A second sealing portion 36 (e.g., a resin, a resin portion, or a sealing resin) is provided on the first surface 13a of the board 13. The second sealing portion 36 covers the controller chip 15 and the bonding wires 35 and protects the controller chip 15 and the bonding wires 35.

The controller chip 15 controls, for example, the overall operation of the semiconductor device 1. The controller chip 15 performs control (e.g., access control) for the memory card 14. That is, the controller chip 15 controls a data writing operation, a data storage operation, a data reading operation, and a data deletion operation for the memory card 14.

The controller chip 15 is disposed between the memory card 14 and the connector 12 on the first surface 13a of the board 13. The controller chip 15 is electrically connected to the terminals 29 of the memory card 14 and the terminals 21 of the connector 12. In this way, the terminals 21 of the connector 12 are electrically connected to the terminals 29 of the memory card 14 via the controller chip 15. Power is supplied from the external apparatus 2 to the semiconductor device 1 via, for example, the connector 12 and the controller chip 15.

FIG. 5 is a diagram schematically illustrating the electrical connection among the controller chip 15, the memory card 14, and the connector 12. As illustrated in FIG. 5, first wiring lines 41 are provided between the controller chip 15 and the memory card 14. The first wiring line 41 is, for example, a first wiring pattern provided on the board 13.

The first wiring lines 41 electrically connect the controller chip 15 and the pads 31 of the board 13. In this way, the first wiring lines 41 are electrically connected to the terminals 29 of the memory card 14 via the pads 31 of the board 13 and the bonding wires 32. In other words, the controller chip 15 is electrically connected to the terminals 29 of the memory card 14 through the first wiring lines 41. The number of first wiring lines 41 is equal to, for example, the number of terminals 29 of the memory card 14 and is, for example, eight. Signals which are in one-to-one correspondence with the terminals 29 of the memory card 14 flow through the first wiring lines 41.

Second wiring lines 42 are provided between the controller chip 15 and the terminals 21 of the connector 12. The second wiring line 42 is, for example, a second wiring pattern provided on the board 13. The second wiring lines 42 electrically connect the controller chip 15 and the terminals 21 of the connector 12. The number of second wiring lines 42 is equal to, for example, the number of terminals 21 of the connector 12 and is, for example, four. Signals which are in one-to-one correspondence with the terminals 21 of the connector 12 flow through the second wiring line 42.

The controller chip 15 performs conversion between a signal corresponding to the standard of the memory card 14 and a signal corresponding to the standard of the connector 12. In this embodiment, the controller chip 15 is a conversion controller between a memory card interface and a USB interface. That is, in this embodiment, the controller chip 15 performs conversion between a signal corresponding to the standard of the “micro SD card” and a signal corresponding to the USB standard. In other words, the controller chip 15 performs conversion between signals flowing through the eight terminals 29 of the memory card 14 and signals flowing through the four terminals 21 of the connector 12.

As illustrated in FIGS. 3 and 4, a plurality of electronic components 16 (e.g., functional components) are attached to the second surface 13b of the board 13. The electronic component 16 is, for example, a resistor or a capacitor. The electronic components 16 are fixed to the second surface 13b of the board 13 by, for example, solder. That is, in this embodiment, components which are connected by the bonding wires are mounted on the first surface 13a of the board 13 and components which are fixed by solder are mounted on the second surface 13b of the board 13.

As illustrated in FIGS. 3 and 4, a test portion 44 is provided at the second end 24 of the board 13. The test portion 44 includes a plurality of terminals 45 (i.e., connection portions or conductive portions, e.g., pads, test pads, or test portions). The terminals 45 are exposed to the outside of the board 13 and are provided in the housing 11 such that it is not seen from the outside of the housing 11. On the other hand, with the housing 11 removed, the terminals 45 of the test portion 44 are exposed to the outside, and terminals (i.e., external test terminals) of an external test device can be connected to the terminals 45.

In this embodiment, a plurality of test terminals 45 are arranged as a test portion 44 in a predetermined region of the board 13. Specifically, the plurality of terminals 45 are arranged side by side at the second end 24 of the board 13 along the second end 24. The terminals 45 are disposed so as to be opposite to the connector 12, the memory card 14 and the controller chip 15 being therebetween.

As illustrated in FIGS. 4 and 5, the number of terminals 45 is greater than, for example, the number of terminals 21 of the connector 12. The number of terminals 45 is equal to, for example, the number of terminals 29 of the memory card 14 and is, for example, eight. The terminals 45 are directly electrically connected to the memory card 14.

In the specification, the term “direct electrical connection to the memory card 14 (i.e., a semiconductor component or a semiconductor memory component)” means electrical connection to the memory card 14 (i.e., a semiconductor component or a semiconductor memory component) without via a controller (e.g., the controller chip 15) which is provided outside the memory card 14 (i.e., a semiconductor component or a semiconductor memory component).

As illustrated in FIG. 5, third wiring lines 46 are provided between the terminals 45 of the test portion 44 and the memory card 14. The third wiring line 46 is, for example, a third wiring pattern provided on the board 13. The third wiring lines 46 electrically connect the terminals 45 of the test portion 44 and the pads 31 of the board 13. In this way, the third wiring lines 46 are electrically connected to the terminals 29 of the memory card 14 via the pads 31 and the bonding wires 32 of the board 13. In other words, the terminals 45 of the test portion 44 are electrically connected to the terminals 29 of the memory card 14 through the third wiring lines 46. That is, the terminals 45 of the test portion 44 are electrically connected to the terminals 29 of the memory card 14, without via the controller chip 15.

The number of third wiring lines 46 is equal to, for example, the number of terminals 29 of the memory card 14 and is, for example, eight. Signals which are in one-to-one correspondence with the terminals 29 of the memory card 14 flow through the third wiring lines 46. In this way, the plurality of terminals 45 of the test portion 44 and the plurality of terminals 29 of the memory card 14 are electrically connected to each other in one-to-one manner.

As illustrated in FIG. 4, the shape of the terminal 45 of the test portion 44 follows the shape of the terminal 29 of the memory card 14. That is, the shape of the terminal 45 of the test portion 44 is substantially the same as that of the terminal 29 of the memory card 14. The arrangement (i.e., array) of the plurality of terminals 45 of the test portion 44 is substantially the same as the arrangement (i.e., array) of the plurality of terminals 29 of the memory card 14.

For example, the width of each terminal 45 of the test portion 44 and the interval between the plurality of terminals 45 are substantially equal to the width of each terminal 29 of the memory card 14 and the interval between the plurality of terminals 29, respectively. In other words, the terminals 45 of the test portion 44 are arranged in, for example, the standard array of the “micro SD card”. In addition, the terminals 45 of the test portion 44 may be arranged in, for example, the standard array of the “mini SD card”, the “SD card”, or other memory cards.

The plurality of terminals 45 of the test portion 44 are arranged in, for example, the same order as that in which the plurality of terminals 29 of the memory card 14 are arranged. That is, for example, one terminal 45 which is disposed at the end among the plurality of terminals 45 of the test portion 44 are electrically connected to one terminal 29 which is disposed at the end among the plurality of terminals 29 of the memory card 14. For example, the third terminal 45 from the end among the plurality of terminals 45 of the test portion 44 is electrically connected to the third terminal 29 from the end among the plurality of terminals 29 of the memory card 14. In addition, the order in which the plurality of terminals 45 of the test portion 44 are arranged may be opposite to the order in which the plurality of terminals 29 of the memory card 14 are arranged in the lateral direction.

As illustrated in FIGS. 3 and 4, no component is mounted on the terminals 45 of the test portion 44, and the terminals 45 are available. Therefore, the terminals (i.e., external test terminals) of an external test device, which is an external apparatus (i.e., a second external apparatus), can be connected to the terminals 45 of the test portion 44, with at least a portion of the housing 11 removed from the board 13.

That is, the external test terminals can be connected (i.e., electrically connected) to the terminals 45 of the test portion 44 to supply signals to the terminals 45 of the test portion 44 or to receive signals from the terminals 45 of the test portion 44. In addition, an example of the terminal of the test device is a test terminal corresponding to the standard of the “micro SD card”, the “mini SD card”, the “SD card”, or other memory cards.

Next, a method of testing the semiconductor device 1 according to this embodiment will be described.

The semiconductor device 1 is tested, for example, after manufacture. In the test for the semiconductor device 1, first, the connector 12 (e.g., a USB connector) of the semiconductor device 1 is connected to the first test device and the operation of the semiconductor device 1 is checked through the connector 12. Then, when it is checked that the semiconductor device 1 operates normally, the test ends.

On the other hand, in the test, when the semiconductor device 1 does not operate normally, a defect analysis for specifying a defective portion is needed. In the test through the connector 12, in some cases, it is difficult to easily analyze whether there is a defect in the controller chip 15 or the memory card 14 (i.e., a semiconductor component or a semiconductor memory component).

In this case, the test portion 44 is used to test the semiconductor device 1, with the housing 11 removed. Specifically, the terminals (i.e., the external test terminals) of the second test device are connected to the terminals 45 of the test portion 44 and the operation of the memory card 14 is checked without via the controller chip 15. When it is checked that the memory card 14 operates normally, additional analysis is performed for the controller chip 15. On the other hand, when it is checked that the memory card 14 does not operate normally, additional analysis is performed for the memory card 14.

According to the semiconductor device 1 of this embodiment, it is possible to improve the ease of the test (e.g., defect analysis). That is, the semiconductor device 1 according to this embodiment includes the housing 11, the board 13 in the housing 11, a semiconductor component (e.g., a memory card) on the board 13, a controller (e.g., the controller chip 15) on the board 13, the terminals 21 exposed to the outside of the housing 11 and electrically connected to the semiconductor component via the controller, and the terminals 45 on the board 13 in the housing 11 electrically connected to the semiconductor component. According to this structure, the test using the terminals 45 can check the operation of the semiconductor component, without involving the controller. Therefore, it is easy to specify a defective portion and it is possible to improve the ease of the test.

In this embodiment, the terminals 45 of the test portion 44 are opposite to the terminals 21 of the connector 12, the semiconductor component being therebetween. In other words, the semiconductor component is disposed between the terminals 21 of the connector 12 and the terminals 45 of the test portion 44. Therefore, it is possible to reduce the wiring distance between the terminals 21 of the connector 12 and the semiconductor component and reduce the wiring distance between the terminals 45 of the test portion 44 and the semiconductor component.

When the wiring distance between the terminals 45 of the test portion 44 and the semiconductor component can be reduced, the influence of noise on the signals flowing to the terminals 45 of the test portion 44 can be reduced. Therefore, it is possible to improve the accuracy of analysis.

In this embodiment, the semiconductor device 1 includes the housing 11, the board 13 in the housing 11, a semiconductor memory component (e.g., the memory card 14) on the board 13, the controller chip 15 on the board 13, the connector 12 attached to the board 13, and the plurality of terminals 45 arranged at the end of the board 13. The connector 12 includes the plurality of terminals 21 electrically connected to the semiconductor memory component via the controller chip 15, exposed to the outside of the housing 11, and connectable to the external apparatus 2. The plurality of terminals 45 are in the housing 11 and are electrically connected to the semiconductor memory component without via the controller chip 15. The external test terminals can be connected to the terminals 45, with at least a portion of the housing 11 removed.

According to this structure, it is possible to check the operation of the semiconductor memory component using the test using the terminals 45 of the test portion 44, in addition to the test using the connector 12. In this way, it is easy to specify a defective portion and it is possible to improve the ease of the test.

In this embodiment, the board 13 includes the first end 23 to which the connector 12 is attached and the second end 24 opposite to the first end 23. The plurality of terminals 45 are arranged at the second end 24 of the board 13. That is, the plurality of terminals 45 are collectively arranged at the second end 24 of the board 13. Therefore, it is easy to connect the terminals of the test device to the terminals 45 of the test portion 44 and it is possible to improve the ease of the test.

In this embodiment, the number of terminals 45 of the test portion 44 is greater than the number of terminals 21 of the connector 12. Therefore, the test using the terminals 45 of the test portion 44 can improve the accuracy of the test, as compared to the test using the terminals 21 of the connector 12. As a result, it is possible to improve the ease of the test.

For example, it is also considered that a memory card socket is provided on the board 13 and the memory card 14 is attached to the socket to mount the memory card on the board 13, instead of connecting the memory card 14 to the board 13 using the bonding wires 32. However, in this case, the costs of the socket are incurred and it is difficult to reduce the costs of the semiconductor device 1.

In this embodiment, the semiconductor device 1 includes the housing 11, the board 13 in the housing 11, the memory card 14, the bonding wires 32, the sealing portion 33, the chip 15 mounted on the board 13, the connector 12 attached to the board 13, and the plurality of terminals 45 arranged at the end of the board 13. The memory card 14 is attached to the board 13, with the plurality of terminals 29 facing the side of the memory card 14 opposite to the board 13. The bonding wires 32 connect the terminals 29 of the memory card 14 and the board 13. The sealing portion 33 covers the bonding wires 32. The connector 12 includes the plurality of terminals 21 which are electrically connected to the memory card 14 via the controller chip 15, is exposed to the outside of the housing 11, and is connectable to the external apparatus 2. The plurality of terminals 45 are disposed in the housing 11 and are electrically connected to the memory card 14 without via the controller chip 15. The external test terminals can be connected to the terminals 45, with at least a portion of the housing 11 removed.

According to this structure, it is possible to omit the socket to which the memory card 14 is attached and thus reduce the costs of the semiconductor device 1. In the structure with the reducing costs, it is possible to test the memory card 14 which is connected to the board 13 by the bonding wires 32, without removing the memory card 14 from the board 13. In this way, it is possible to further improve the ease of the test.

In this embodiment, the number of terminals 45 of the test portion 44 is equal to the number of terminals 29 of the memory card 14 and the terminals 45 of the test portion 44 are electrically connected to the plurality of terminals 29 of the memory card 14 in a one-to-one manner. In this way, the test using the terminals 45 of the test portion 44 can improve the accuracy of the test, as compared to the test using the terminals 29 of the memory card 14. As a result, it is possible to further improve the ease of the test.

In this embodiment, the arrangement of the plurality of terminals 45 of the test portion 44 is substantially the same as that of the plurality of terminals 29 of the memory card 14. According to this structure, it is possible to test the signals of the terminals 45 of the test portion 44 using a test device corresponding to the standard of the memory card 14. Therefore, it is possible to further improve the ease of the test.

### Second Embodiment

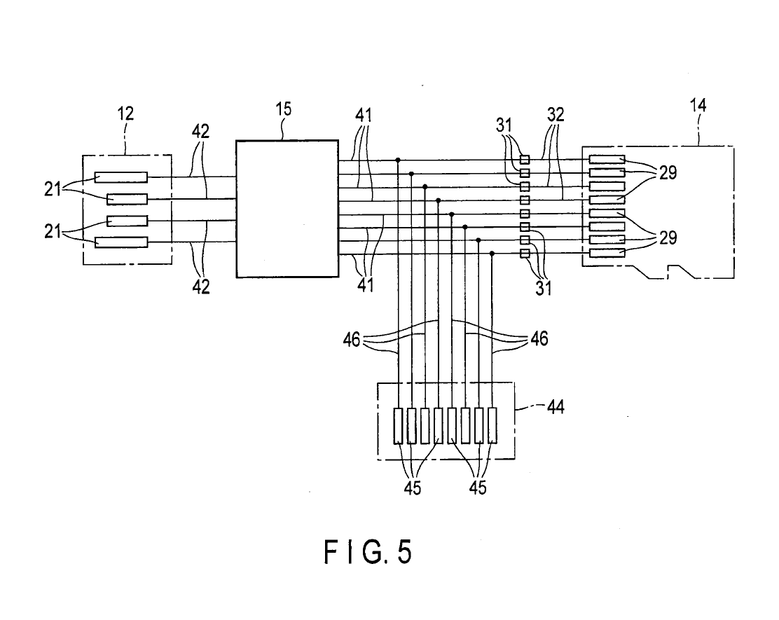

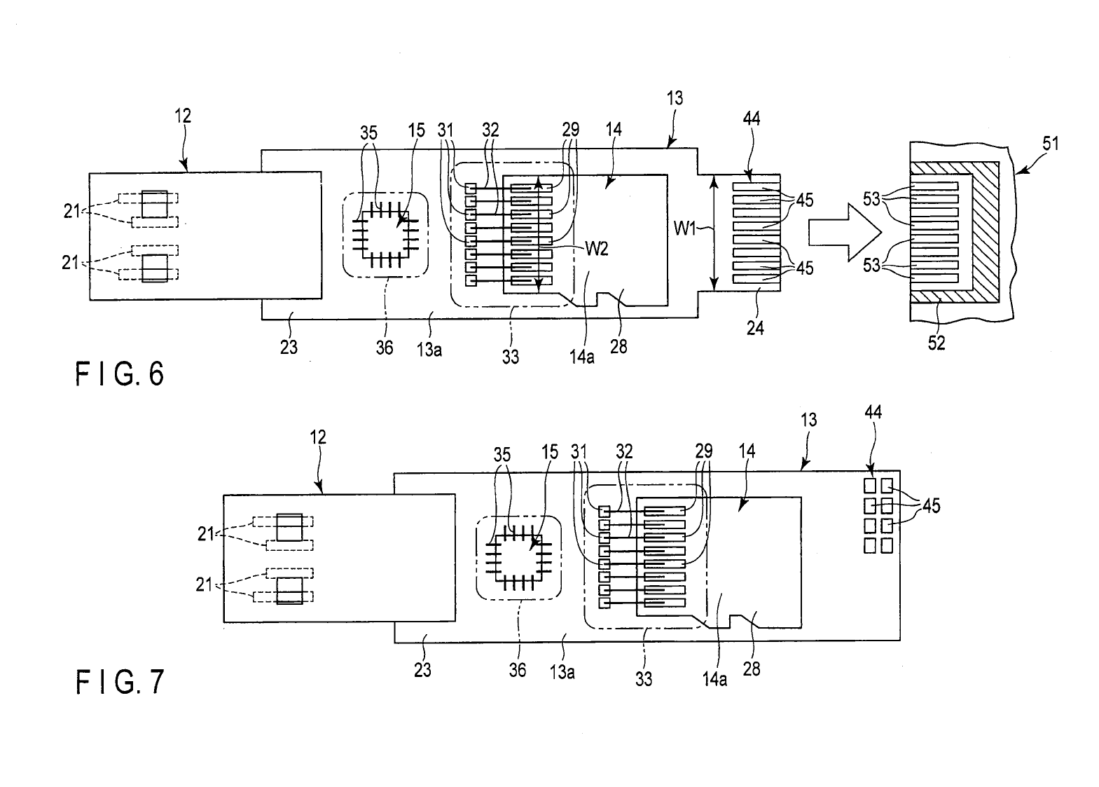

Next, a semiconductor device 1 according to a second embodiment will be described with reference to FIG. 6. In the second embodiment, components having the same or similar functions as those in the first embodiment are denoted by the same reference numerals and the description thereof will not be repeated. In addition, structures other than the following structures are the same as those in the first embodiment.

As illustrated in FIG. 6, in this embodiment, a second end 24 of a board 13 is narrower than the other portions (e.g., a central portion or a first end 23) of the board 13. The shape of the second end 24 of the board 13 is substantially the same as that of the end (e.g., the insertion-side end) of the memory card 14. That is, the width W1 of the second end 24 is substantially equal to, for example, the width W2 of the insertion-side end of the memory card 14. That is, in this embodiment, the shape of a portion of the board 13 around terminals 45 follows the shape of an insertion portion of the memory card 14 (i.e., corresponds to the standard of the memory card).

The second end 24 of the board 13 can be inserted into a connector 52 of an external test device 51, which is, for example, an external apparatus (i.e., a second external apparatus), with the housing 11 removed. In this embodiment, the external test device 51 is, for example, a memory card test device and includes a test connector 52 corresponding to the standard of the memory card 14. The connector 52 is, for example, a socket or a slot of a “micro SD card”. The connector 52 includes terminals 53 (i.e., external test terminals, connection terminals, connection portions, or conductive portions) based on the standard of the memory card 14.

The terminals 45 of the test portion 44 are provided at the second end 24 of the board 13 and are inserted into the connector 52 of the external test device 51. The terminals 45 of the test portion 44 come into contact with the terminals 53 of the connector 52 and are electrically connected to (i.e., contact) the terminals 53 of the connector 52.

According to this structure, similarly to the first embodiment, it is possible to improve the ease of the test. Furthermore, in this embodiment, it is possible to test the memory card 14 mounted on the board 13 only by inserting the second end 24 of the board 13 into the connector 52 (for example, a socket or a slot of the memory card test device) of the test device 51.

Therefore, it is possible to further improve the ease of the test. The connector 52 of the test device 51 is not limited to the socket or slot of the “micro SD card”, but may be, for example, a socket or a slot of a “mini SD card”, an “SD card”, or memory cards based on other standards.

### Third Embodiment

Next, a semiconductor device 1 according to a third embodiment will be described with reference to FIG. 7. In the third embodiment, components having the same or similar functions as those in the first embodiment are denoted by the same reference numerals and the description thereof will not be repeated. In addition, structures other than the following structures are the same as those in the first embodiment.

As illustrated in FIG. 7, in this embodiment, terminals 45 of a test portion 44 are arranged at one corner of a board 13. According to this structure, similarly to the first embodiment, it is possible to improve the ease of the test. The arrangement position of the terminals 45 of the test portion 44 is not limited to those according to the first to third embodiments, but the terminals 45 of the test portion 44 may be arranged at other ends or corners of the board 13.

### Fourth Embodiment

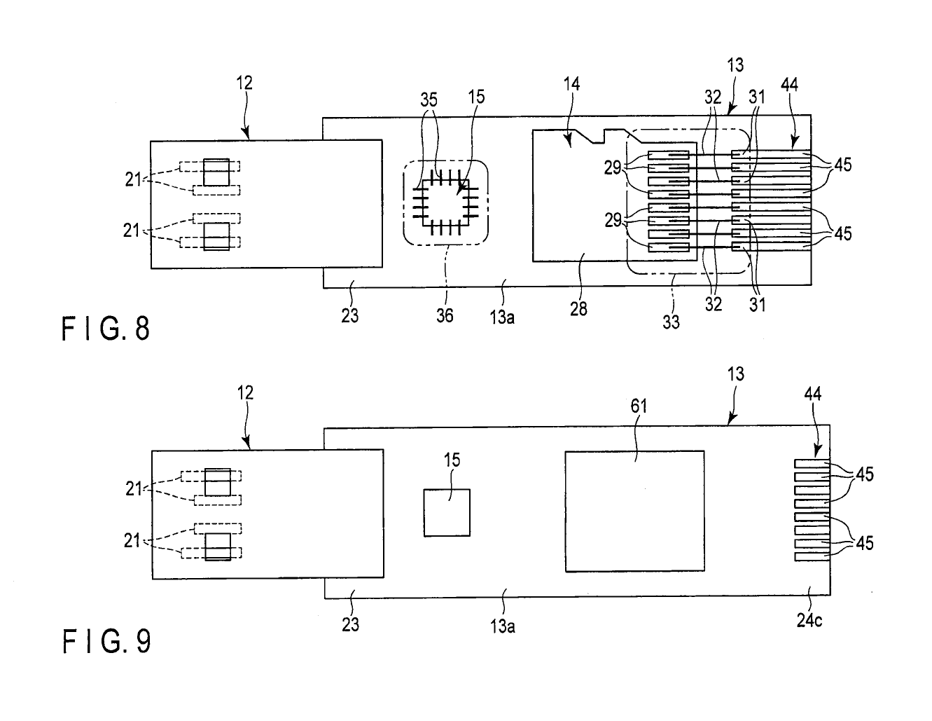

Next, a semiconductor device 1 according to a fourth embodiment will be described with reference to FIG. 8. In the fourth embodiment, components having the same or similar functions as those in the first embodiment are denoted by the same reference numerals and the description thereof will not be repeated. In addition, structures other than the following structures are the same as those in the first embodiment.

As illustrated in FIG. 8, in this embodiment, a memory card 14 is attached to a board 13, with an end which is close to terminals 29 facing a second end 24 of the board 13. Pads 31 of the board 13 are provided integrally with terminals 45 of a test portion 44. Terminals 21 of a connector 12 are electrically connected to the memory card 14 via a controller chip 15 and the pads 31 of the board 13 (or the terminals 45 of the test portion 44).

According to this structure, similarly to the first embodiment, it is possible to improve the ease of the test. In this embodiment, the pads 31 of the board 13 are provided integrally with the terminals 45 of the test portion 44. Therefore, it is possible to reduce a space required for the pads 31 of the board 13 and the terminals 45 of the test portion 44 and thus reduce the size of the semiconductor device 1.

In addition, when the pads 31 of the board 13 are provided integrally with the terminals 45 of the test portion 44, it is possible to omit the third wiring lines 46 according to the first embodiment and thus simplify the wiring layout of the board 13. Furthermore, when the pads 31 of the board 13 are provided integrally with the terminals 45 of the test portion 44, it is possible to reduce the distance (e.g., the wiring distance) between the terminals 29 of the memory card 14 and the terminals 45 of the test portion 44. Therefore, signals flowing to the terminals 45 of the test portion 44 are less likely to be affected by noise and it is possible to improve the accuracy of the test.

### Fifth Embodiment

Next, a semiconductor device 1 according to a fifth embodiment will be described with reference to FIG. 9. In the fourth embodiment, components having the same or similar functions as those in the first embodiment are denoted by the same reference numerals and the description thereof will not be repeated. In addition, structures other than the following structures are the same as those in the first embodiment.

As illustrated in FIG. 9, in this embodiment, a semiconductor chip 61 is, for example, a package component and is mounted on a first surface 13a of a board 13 by solder, not wire bonding. The semiconductor chip 61 is an example of a “semiconductor component” or a “semiconductor memory component”. The semiconductor chip 61 is, for example, a semiconductor memory chip and an example of the semiconductor memory chip is a NAND flash memory chip. Terminals 45 of a test portion 44 are electrically connected to, for example, the semiconductor chip 61.

In this embodiment, a controller chip 15 is, for example, a package component is connected to the first surface 13a of the board 13 by solder, not wire bonding.

According to this structure, similarly to the first embodiment, it is possible to improve the ease of the test.

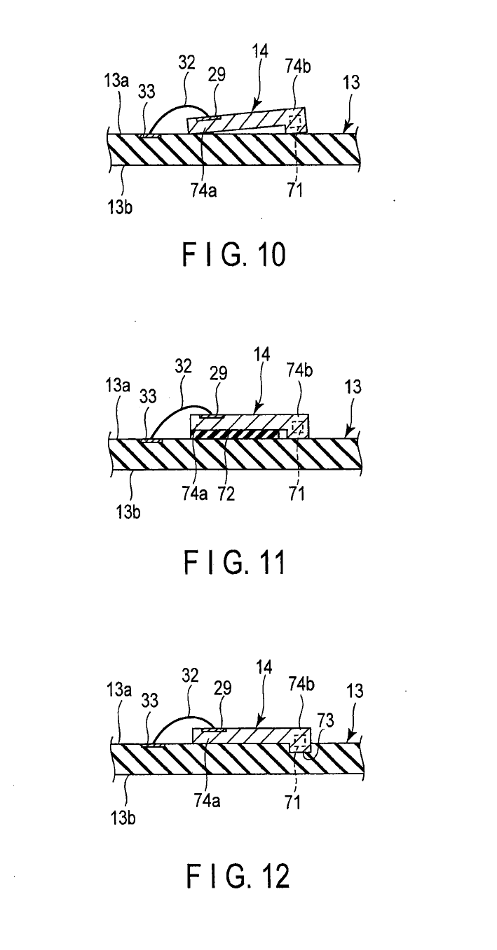

Next, modifications of the first to fourth embodiments will be described with reference to FIGS. 10 to 12.

A memory card 14 includes a first end 74a and a second end 74b which is thicker than the first end 74a. For example, a component 71 is provided at the second end 74b.

FIG. 10 is a diagram illustrating a structure according to a first modification. As illustrated in FIG. 10, a memory card 14 is provided so as to be inclined such that a first end 74a and a second end 74b come into contact with a first surface 13a of a board 13.

FIG. 11 is a diagram illustrating a structure according to a second modification. As illustrated in FIG. 11, a supporter 72 (e.g., a spacer) is inserted between a first end 74a of a memory card 14 and a first surface 13a of a board 13. The supporter 72 separates the first end 74a from the first surface 13a of the board 13. In this way, the memory card 14 is substantially parallel to the first surface 13a of the board 13.

FIG. 12 is a diagram illustrating a structure according to a third modification. As illustrated in FIG. 12, a recess 73 is provided in a first surface 13a of a board 13. A second end 74b of a memory card 14 is inserted into the recess 73. In this way, the memory card 14 is substantially parallel to the first surface 13a of the board 13. The second end 74b of the memory card 14 is inserted into the recess 73 to align (i.e., position) the memory card 14.

According to the structures of the first to fifth embodiments and the modifications thereof, it is possible to improve the ease of the test for the semiconductor device 1.

The structures according to the first to fifth embodiments and the modifications thereof can be changed in various ways. For example, the number of semiconductor chip 61 (or memory cards 14) mounted on the board 13 is not limited to one, but may be two or more. A combination of the shape of the memory card 14 and the shape of the terminals 45 of the test portion 44 is not limited to the combination based on the same memory card standard, but may be a combination of different memory card standards. For example, an “SD card” may be provided as the memory card 14 and the shape of the terminals 45 of the test portion 44 may follow the shape of a “micro SD card”.

The position of the terminals 45 of the test portion 44 is not limited to the above-mentioned example, but the terminals 45 may be provided at any position of the board 13. In the first to fourth embodiments, the controller chip and the semiconductor component (e.g., a semiconductor memory component) may be package components which are soldered to the board 13. The controller chip 15 and the semiconductor component (e.g., a semiconductor memory component or the memory card 14) may be separately provided on the first surface 13a and the second surface 13b of the board 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a housing;
a board in the housing;
a memory card comprising first terminals, the memory card attached to the board with the first terminals facing opposite to the board;
bonding wires connecting first terminals of the memory card and the board;
a sealing portion covering the bonding wires;
a controller chip on the board;
a connector attached to the board, comprising second terminals electrically connected to the memory card via the controller chip, the connector exposed to an outside of the housing and connectable to an external apparatus; and
third terminals arranged at an end of the board in the housing and electrically connected to the memory card without via the controller chip, and, with the housing removed, connectable to external test terminals.

2. The device of claim 1,
wherein the number of third terminals is equal to the number of first terminals, and
the third terminals are electrically connected to the first terminals in a one-to-one manner.

3. The device of claim 1,
wherein an arrangement of the third terminals is substantially the same as an arrangement of the first terminals.

4. The device of claim 3,
wherein the board comprises a first end to which the connector is attached,
the end at which third terminals are arranged is a second end of the board opposite to the first end, and
the second end has substantially the same shape as an end of the memory card and, with the housing removed, is insertable into a connector of an external test device corresponding to the memory card.

5. A semiconductor device comprising:
a housing;
a board in the housing;
a semiconductor memory component on the board;
a controller chip on the board;
a connector attached to the board, the connector comprising first terminals electrically connected to the semiconductor memory component via the controller chip, the connector exposed to an outside of the housing and connectable to an external apparatus; and
second terminals arranged at an end of the board in the housing and electrically connected to the semiconductor memory component without via the controller chip, and, with the housing removed, connectable to external test terminals.

6. The device of claim 5,
wherein the second terminals are opposite to the first terminals, the semiconductor memory component and the controller chip being therebetween.

7. The device of claim 5,
wherein the board comprises a first end to which the connector is attached, and
the end at which third terminals are arranged is a second end opposite to the first end.

8. The device of claim 7,
Wherein, with the housing removed, the second end of the board is insertable into a connector of an external test device.

9. The device of claim 5,
wherein the number of the second terminals is greater than the number of the first terminals.

10. A semiconductor device comprising:
a housing;
a board in the housing;
a semiconductor component on the board;
a controller on the board;
a first terminal exposed to an outside of the housing and electrically connected to the semiconductor component via the controller; and
a second terminal on the board in the housing, the second terminal electrically connected to the semiconductor component.

11. The device of claim 10,
wherein the second terminal is located opposite to the first terminal, the semiconductor component being therebetween.

12. The device of claim 10,
wherein the board comprises an end, with the housing removed, the end is insertable into a connector of an external apparatus, and
the second terminal is at the end of the board and is electrically connectable to the connector.
